(19) United States
(12) Patent Application Publication
(10) Pub. No.: US 2013/0269876 A1
(43) Pub. Date: Oct. 17, 2013

(54) APPARATUS FOR FABRICATING SEMICONDUCTOR DEVICE

(71) Applicant: SAMSUNG ELECTRONICS CO., LTD., Suwon-si (KR)

(72) Inventors: Ik-Soo KIM, Yongin-City (KR); Ho-Gon KIM, Hwaseong-si (KR); Yong-Taek HONG, Suwon-si (KR); Kyoung-Hwan KIM, Yongin-City (KR); Hee-Seok KIM, Seongnam-si (KR); Sung-Ho HAN, Seoul (KR)

(73) Assignee: SAMSUNG ELECTRONICS CO., LTD., Suwon-si (KR)

(21) Appl. No.: 13/795,474

(22) Filed: Mar. 12, 2013

(30) Foreign Application Priority Data
Apr. 13, 2012 (KR) 10-2012-0038563

(51) Int. Cl. H01L 21/3065; H01L 21/02

(52) U.S. Cl. CPC H01L 21/3065; H01L 21/02104
USPC 156/345.34; 156/345.33; 118/715; 118/719

(57) ABSTRACT

An apparatus for fabricating a semiconductor device includes a chamber, a processing part inside the chamber, a gas injection pipe connected to the chamber, a gas pumping pipe connected to the chamber, and a baffle assembly embedded in a chamber wall, and the baffle assembly includes a baffle plate having baffle holes, and a baffle guide surrounding an outer surface of the baffle plate.

### CROSS-REFERENCE TO RELATED APPLICATION

This application claims priority under 35 U.S.C. §119 to Korean Patent Application No. 10-2012-0038563 filed on Apr. 13, 2012, and entitled “APPARATUS FOR FABRICATING SEMICONDUCTOR DEVICE,” the entire disclosure of which is hereby incorporated by reference.

### BACKGROUND

1. Field

Embodiments relate to an apparatus for fabricating a semiconductor device and a method of fabricating the semiconductor device using the apparatus.

2. Description of Related Art

As semiconductor technology progresses, design rules of the semiconductor device may become reduced. Also, as the structure of semiconductor devices becomes increasingly complicated to manufacture, the importance of quality characteristics of films may increase.

### SUMMARY

Embodiments are directed to an apparatus for fabricating a semiconductor device including a chamber, a processing part inside the chamber, a gas injection pipe connected to the chamber, a gas pumping pipe connected to the chamber, and a baffle assembly embedded in a wall of the chamber, where the baffle assembly includes a baffle plate having baffle holes, and a baffle guide surrounding an outer surface of the baffle plate.

The baffle plate may have a shape of a ring.

The baffle holes may be arranged along a single horizontal line in the baffle plate.

The baffle holes may have various sizes.

The baffle holes may include a recess on a front side of the baffle plate.

The baffle plate may further include insertion pins inserted into the respective baffle holes.

Each of the insertion pins may include a body having a diameter smaller than that of the respective baffle holes, and a flange having a diameter larger than that of the respective baffle holes.

The body may have a shape of a cylinder, and the flange may have a flat zone.

The flat zone may be inserted into the baffle plate.

Each of the insertion pins may further include a pin hole in the flange.

The pin holes may have varying positions in the flange of each of the insertion pins.

At least one of the insertion pins may have a first pin hole and a second pin hole.

The first pin hole may have a first diameter and the second pin hole may have a second diameter, and the first diameter may be smaller than the second diameter.

The processing part may include a first processing part and a second processing part, the first processing part and the second processing part may be inside the chamber, the first processing part and the second processing part may share the gas injection pipe and the gas pumping pipe, the first processing part may include a first shower head and a first stage, and the second processing part may include a second shower head and a second stage.

Embodiments are also directed towards an apparatus for fabricating a semiconductor device including a chamber, a first processing part and a second processing part inside the chamber, a gas supplying unit having a first gas distributing pipe and a second gas distributing pipe connected to the inside of the chamber, the first gas distributing pipe and the second gas distributing pipe divaricating from the gas supplying unit and being connected to the first processing part and the second processing part, respectively, a gas pumping unit having a first gas collecting pipe and a second gas collecting pipe connected to the inside of the chamber, the first gas collecting pipe and the second gas collecting pipe being connected to the first processing part and the second processing part, respectively, a first baffle assembly surrounding the first processing part and embedded in a wall of the chamber, the first baffle assembly including a first baffle plate having first baffle holes, and first insertion pins inserted into the first baffle holes, and a second baffle assembly surrounding the second processing part and embedded in the wall of the chamber, the second baffle assembly including a second baffle plate having second baffle holes, and second insertion pins inserted into the second baffle holes.

The first gas collecting pipe and the second gas collecting pipe may divaricate from the gas pumping unit.

The first insertion pins may be inserted into the first baffle holes according to a first arrangement, the second insertion pins may be inserted into the second baffle holes according to a second arrangement, and the first arrangement may be different from the second arrangement.

Embodiments are also directed to an apparatus for fabricating a semiconductor device including a chamber with a gas inlet and a gas outlet, a stage inside the chamber, and a baffle assembly in a gas flow path between the gas inlet and the gas outlet, the baffle assembly including baffle holes defining the gas flow path through the baffle assembly, and at least one pin inside at least one of the baffle holes, the at least one pin at least partially obstructing the gas flow path through the at least one baffle hole.

The baffle assembly may include first and second pins in respective first and second baffle holes, and the first and second pins may obstruct the gas flow path through the respective first and second baffle holes to varying degrees.

The first pin may completely obstruct the gas flow path through the first hole.

### BRIEF DESCRIPTION OF THE DRAWINGS

Features will become apparent to those of skill in the art by describing in detail exemplary embodiments with reference to the attached drawings in which:

FIGS. 1A, 1B, and 1C illustrate top views of an apparatus for fabricating a semiconductor device in accordance with various embodiments;

FIGS. 2A and 2B illustrate vertical sectional views that schematically illustrate the apparatus for fabricating a semiconductor device in accordance with various embodiments;

FIG. 3 illustrates a exploded view that schematically illustrates a baffle assembly in a chamber of an apparatus for fabricating a semiconductor device in accordance with an embodiment;

FIGS. 4A, 4B, and 4C illustrate perspective views that schematically illustrate baffle plates in accordance with various embodiments;

FIGS. 5A, 5B, 5C, 5D, and 5E illustrate perspective views that schematically illustrate the shapes of insertion pins to be inserted into a baffle plate in accordance with various embodiments;

FIGS. 6A and 6B illustrate vertical sectional views that schematically illustrate insertion pins inserted into a baffle plate in accordance with various embodiments; and

FIG. 7 illustrates a flow chart of a method of fabricating a semiconductor device using an apparatus for fabricating the semiconductor device.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers or elements may also be present. Further, it will be understood that when a layer or element is referred to as being “under” another layer or element, it can be directly under, and one or more intervening layers or elements may also be present. In addition, it will also be understood that when a layer or element is referred to as being “between” two layers or elements, it can be the only layer or element between the two layers or elements, or one or more intervening layers or elements may also be present. Like reference numerals refer to like layers or elements throughout.

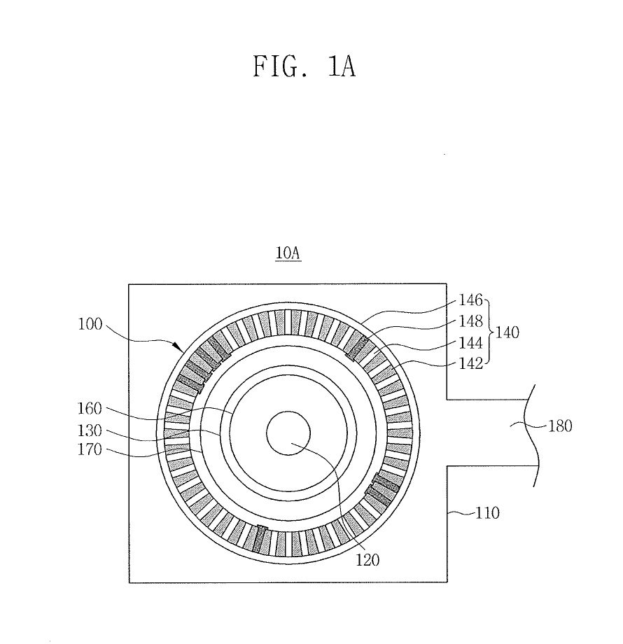

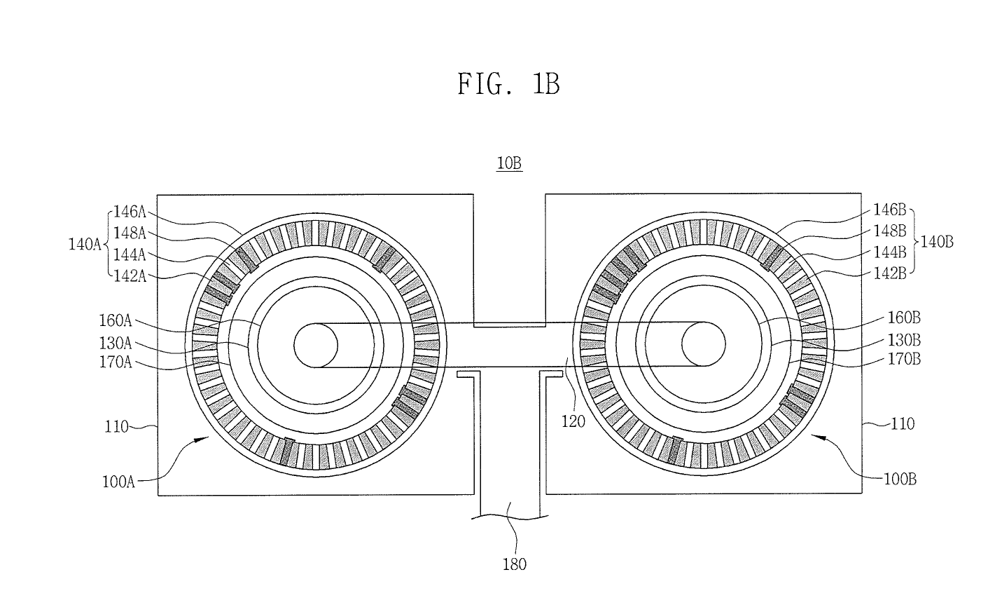

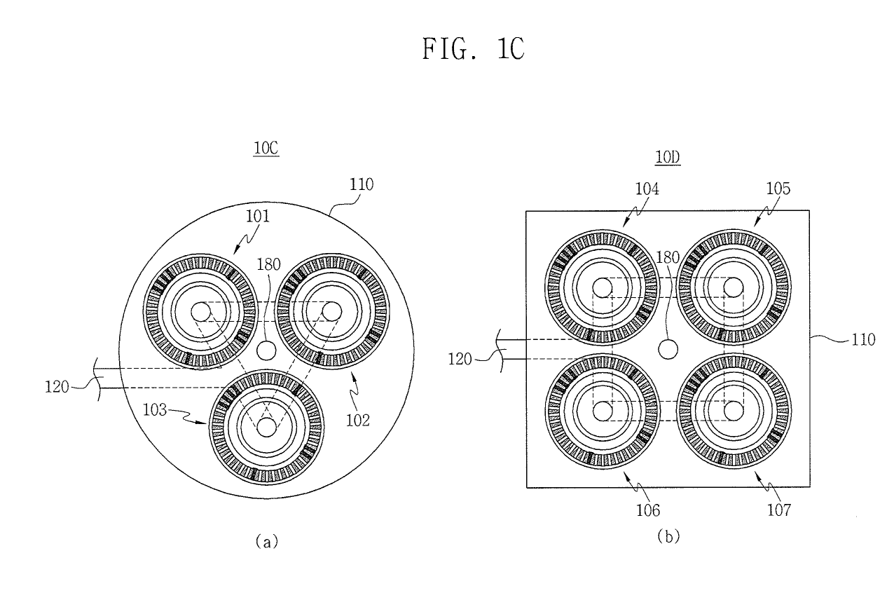

FIGS. 1A, 1B, and 1C illustrate top views of an apparatus for fabricating a semiconductor device in accordance with various embodiments.

Referring to FIG. 1A, an apparatus 10A for fabricating a semiconductor device may include a chamber 110, and a processing part 100 disposed inside the chamber 110. The processing part 100 may include a gas injection pipe 120, a shower head 130, a baffle assembly 140, a stage 170, and a gas pumping pipe 180.

The chamber 110 may be in the shape of a cylinder having a defined inner space. The chamber 110 may have a closed upper part and/or side part. The chamber 110 may be connected to an external gas injection pipe 120.

The gas injection pipe 120 may be positioned in an upper area, a side area, or an upper side area of the chamber 110. The gas injection pipe 120 may supply the gases to a plasma area PA in the inside of the chamber 110. The gas injection pipe 120 may be connected to the shower head 130. The shower head 130 may distribute and supply the gases evenly into the chamber 110.

The baffle assembly 140 may includes a baffle plate 142 and a baffle guide 146 surrounding an outer surface of the baffle plate 142. The baffle plate 142 may be in the shape of a ring. The baffle plate 142 may include a plurality of baffle holes 144. The baffle holes 144 may pass through the inside and outside of the baffle plate 142 radially. The baffle plate 142 may include insertion pins 148 inserted into the plurality of baffle holes 144. The baffle plate 140 will be explained in greater detail below.

The stage 170 may be positioned in a lower area of the chamber 110, for example in a lower middle area. A wafer 160 may be mounted on the stage 170.

The gas pumping pipe 180 may be positioned in a lower area, a side area, or a lower side area of the chamber 110. The gas pumping pipe 180 may maintain a constant pressure in the inside of the chamber 110.

Referring to FIG. 1B, an apparatus 10B for fabricating the semiconductor device may include a first processing part 100A and a second processing part 100B disposed in the inside of the chamber 110.

The first processing part 100A and the second processing part 100B may share the single chamber 110. For example, the first processing part 100A and the second processing part 100B may be in spatial communication. The first processing part 100A and the second processing part 100B may share the gas injection pipe 120 and/or the gas pumping pipe 180. For example, the gas injection pipe 120 may be positioned in an upper area, a side area, or an upper side area of the chamber 110 and the gas pumping pipe 180 may be positioned in a side area or a lower side area of the chamber 110.

As illustrated in FIG. 1B, the insertion pins 148A in the first processing part 100A may be in a different arrangement (e.g., different number of pins, different type/size of pins, different location of pins, or a combination thereof) compared to the insertion pins 148B in the second processing part 100B.

Referring to FIG. 1C, apparatuses 10C and 10D for fabricating the semiconductor device may include at least three or more processing parts 101, 102, 103, 104, 105, 106, and 107 sharing the single chamber 110 or the plasma area PA.

Referring to FIG. 1C (a), the apparatus 10C for fabricating the semiconductor device, for example, may include the three processing parts 101, 102, and 103, which may share the gas injection pipe 120 and the gas pumping pipe 180. The gas injection pipe 120 may be positioned in an upper area, a side area, or an upper side area of the chamber 110. The gas pumping pipe 180 may be positioned in a lower area, a side area, or a lower side area of the chamber 110.

Referring to FIG. 1C (b), the apparatus 10D for fabricating the semiconductor device, for example, may include the four processing parts 104, 105, 106, and 107, which may share the gas injection pipe 120 and the gas pumping pipe 180.

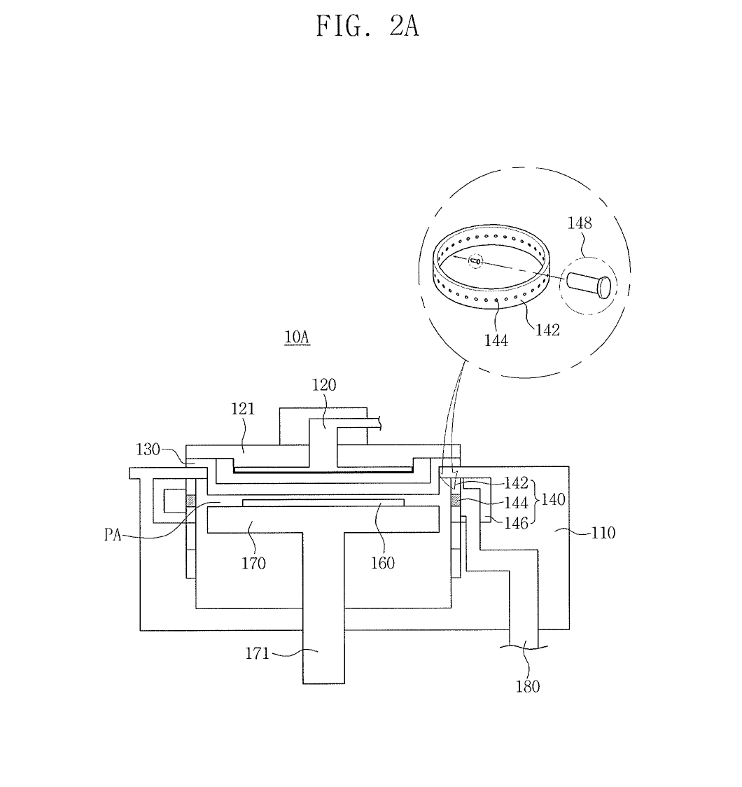

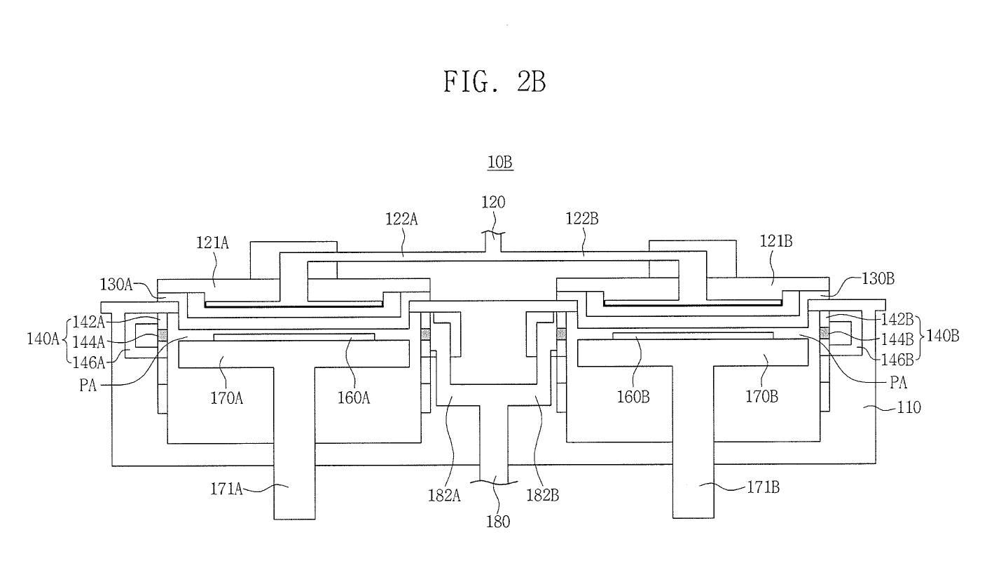

FIGS. 2A and 2B illustrate vertical sectional views that schematically illustrate the apparatus for fabricating a semiconductor device in accordance with various embodiments.

Referring to FIG. 2A, in the apparatus 10A for fabricating the semiconductor device, a processing part 100 may include a gas injection pipe 120 positioned in a middle upper area thereof, a shower head 130 connected to the gas injection pipe 120, a baffle assembly 140, a stage 170 connected to a support 171, and a gas pumping pipe 180. The gas injection pipe 120 may be inserted into the inside of the chamber 110. The gas injection pipe 120 may be connected to a gas storage container 121 at the side thereof. The gas storage container 121 may store nitrogen.

The baffle assembly 140 may includes a baffle plate 142 having baffle holes 144, a baffle guide 146 surrounding an outer surface of the baffle plate 142, and insertion pins 148 inserted into the baffle holes 144.

The support 171 may be positioned in a lower area or a lower side area of the stage 170. For example, the support 171 may pass through a side of the chamber 110 in the shape of a hollow bar. The support 171 may support the stage 170.

The reacting gases may be supplied onto the wafer 160 via the gas injection pipe 120 and the shower head 130. The reacting gases may react with the wafer 160 to form a material layer on the wafer 160 or to remove a material layer from the wafer 160. For example, the apparatus 10A for fabricating the semiconductor device may perform a deposition process or an etching process.

After the reaction, the reacting gases may be discharged to the outside of the chamber 110 through the baffle assembly 140 and the gas pumping pipe 180. For example, the reaction gas may pass through the baffle holes 144 and/or the insertion pins 148 inserted into the baffle hole 144, move along the baffle guide 146 and then be discharged to the outside of the chamber 110 through the gas pumping pipe 180.

Referring to FIG. 2B, the apparatus 10B for fabricating the semiconductor device may include two processing parts 100A and 100B. The two processing parts 100A and 100B may share one gas injection pipe 120 and one gas pumping pipe 180. Each of the processing parts 100A and 100B may include a respective shower head 130A and 130B, baffle assembly 140A and 140B, and stage 170A and 170B. The gas injection pipe 120 may include gas distributing pipes 122A and 122B connected to the shower heads 130A and 130B of each processing part 100A and 100B. The gas pumping pipe 180 may include gas collecting pipes 182A and 182B connected to the respective baffle assemblies 140A and 140B of each processing part 100A and 100B.

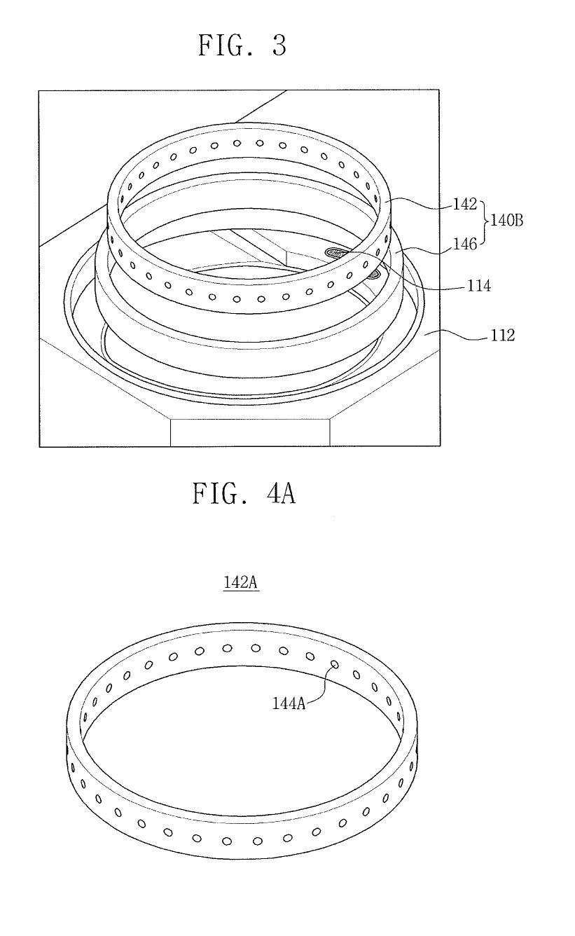

FIG. 3 illustrates a exploded view that schematically illustrates a baffle assembly in a chamber of an apparatus for fabricating a semiconductor device in accordance with an embodiment.

Referring to FIG. 3, the baffle assembly 140 may be embedded in the chamber 110. The baffle guide 146 may surround the outer surface of the baffle plate 142. A chamber wall 112 may include a slit door 114. The slit door 114 may be aligned with the baffle guide 146 so that a passage for the reacting gases to be discharged to the outside, for example, to the gas pumping pipe 180, can be provided. Between the baffle plate 142 and the baffle guide 146, an 0-ring or a gasket (not shown) may be interposed.

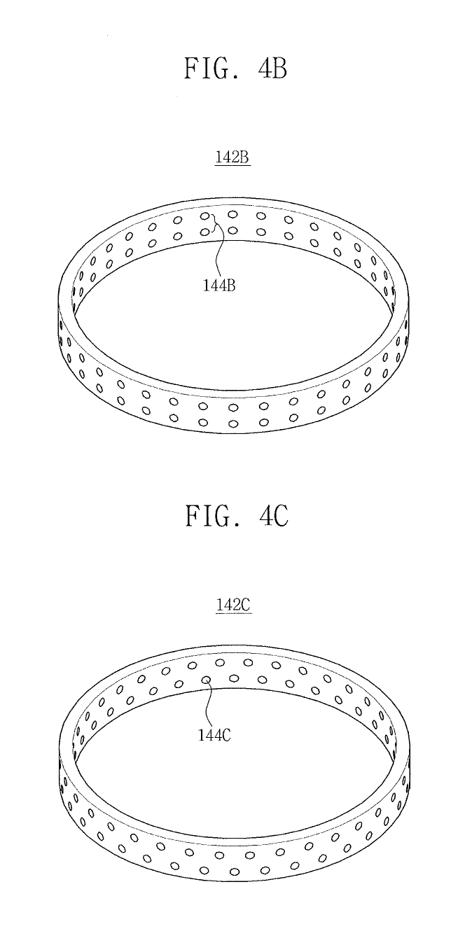

FIGS. 4A, 4B, and 4C illustrate perspective views that schematically illustrate baffle plates in accordance with various embodiments.

Referring to FIG. 4A, a baffle plate 142A may have a plurality of baffle holes 144A arranged along a single horizontal line thereof. The baffle holes 144A may be in various sizes. By way of example, the baffle holes 144A may be arranged along a single horizontal line in the middle of the baffle plate 142. The sizes of the baffle holes 144A may be, for example, about 2 mm to about 12.4 mm in diameter.

Referring to FIG. 4B, a baffle plate 142B may have baffle holes 144B arranged in dual horizontal lines.

Referring to FIG. 4C, a baffle plate 142C may have baffle holes 144C horizontally arranged in a zigzag shape/pattern or in wave shape/pattern. The arrangement of baffle holes in FIGS. 4A, 4B, and 4C are provided by way of example only, and other suitable baffle hole 144 arrangements may also be used.

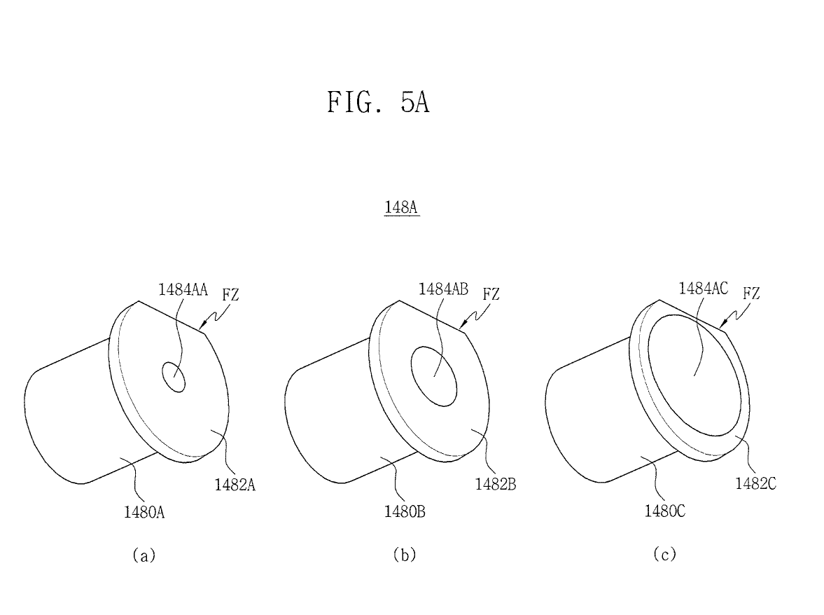

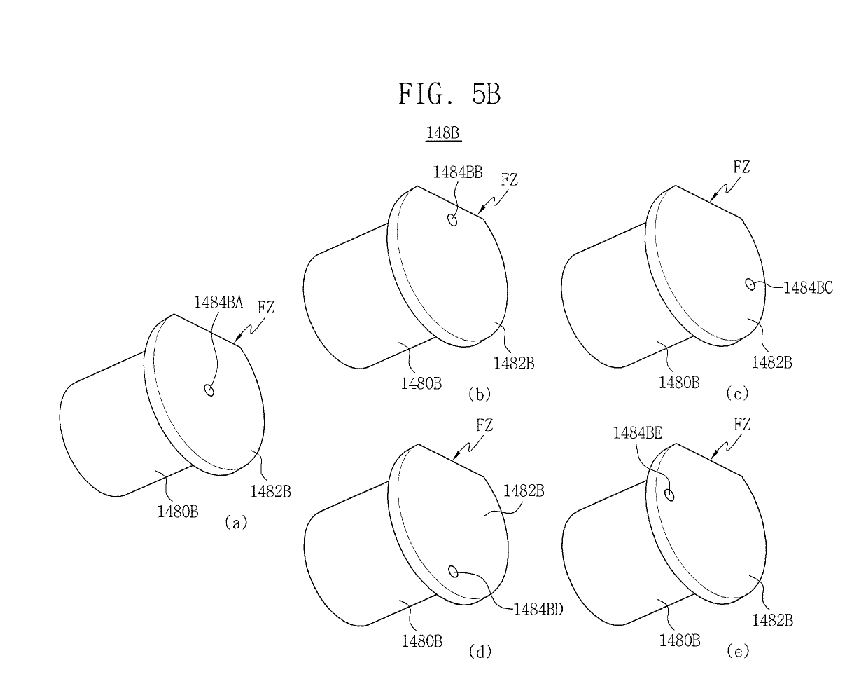

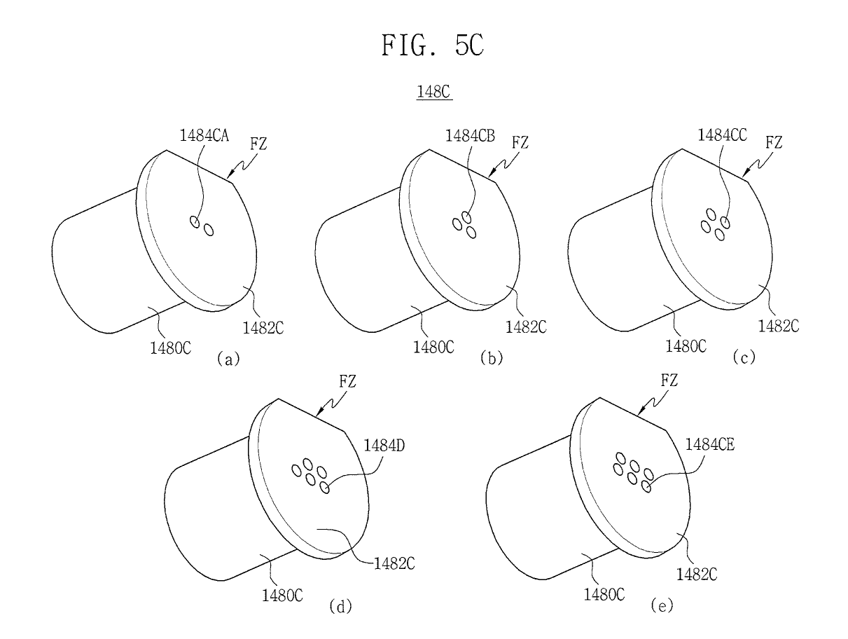

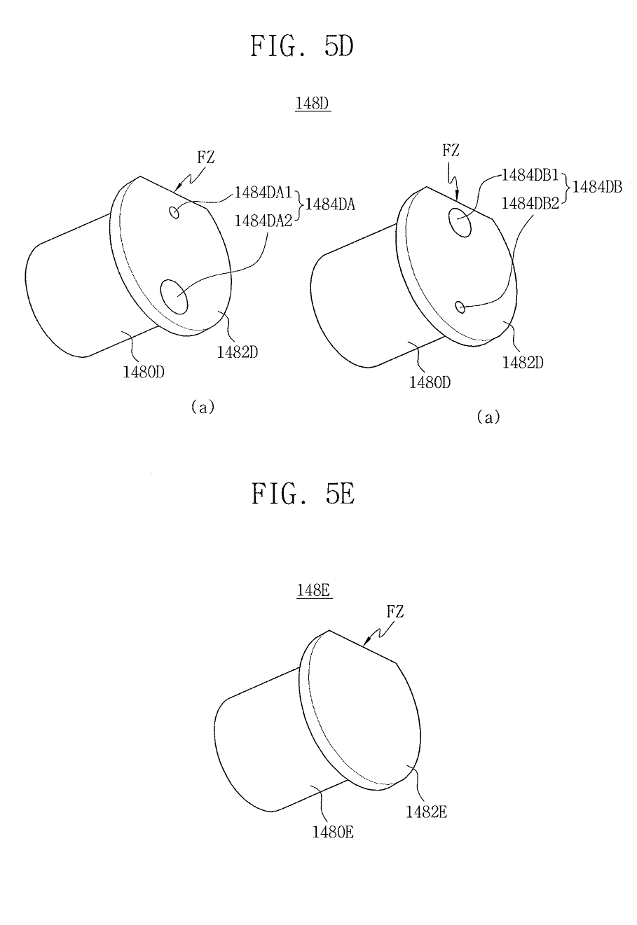

FIGS. 5A, 5B, 5C, 5D, and 5E illustrate perspective views that schematically illustrate the shapes of insertion pins to be inserted into a baffle plate in accordance with various embodiments. Referring to FIG. 5A, insertion pins 148A may include a body 1480A, 1480B, 1480C, a flange 1482A, 1482B, 1482C, and pin holes 1484AA, 1484AB, and 1484AC. The body 1480A may be inserted into the baffle holes 144 in a shape corresponding to the baffle holes 144, e.g., a hollow tube, a pipe, a cylinder, or a pillar. The body 1480A may have a diameter smaller than each of the baffle holes 144. The flange 1482A may be formed on a top surface of the body 1480A and may have a diameter larger than each of the baffle holes 144. The pin holes 1484AA to 1484AC may be formed on a top surface of the flange 1482A and may be formed in various shapes. The pin holes 1484AA to 1484AC may also be formed in various sizes. For example, a small sized pin hole 1484AA, a medium sized pin hole 1484AB, a large sized pin hole 1484AC, etc. may be formed. The pin holes 1484AA to 1484AC may be formed in various sizes, e.g., 2 Ø (phi), 4 Ø, 6 Ø, 8 Ø, 10 Ø, etc.

Referring to FIG. 5B, insertion pins 148B may include pin holes 1484BA, 1484BB, 1484BC, 1484BD, and 1484BE having different positions. The pin holes 1484BA to 1484BE may be formed in various positions. For example, the pin hole 1484BA may be formed in the center of a flange 1482B, the pin hole 1484BB may be formed in the upper side of a flange 1482B, the pin hole 1484BC may be formed in the right side of a flange 1482B, the pin hole 1484BD may be formed in the lower side of a flange 1482B, the pin hole 1484BE may be formed in the left side of a flange 1482B, etc. By way of example, the insertion pins 1484B have been shown as having fine pin holes 1484BA to 1484BE, however the pin holes 1484BA to 1484BE may have other suitable sizes and/or shapes.

Referring to FIG. 5C, insertion pins 148C may include a plurality of unit pin holes 1484CA, 1484CB, 1484CC, 1484CD, and 1484CE. For example, the insertion pin 148C may have the pin hole 1484CA having two holes formed on an upper side center of the flange 1482C, the pin hole 1484CB having three holes formed on an upper side center of the flange 1482C, the pin hole 1484CC having four holes formed on an upper side center of the flange 1482C, the pin hole 1484CD having five holes formed on an upper side center of the flange 1482C, and the pin hole 1484CE having six holes formed on an upper side center of the flange 1482C. The pin holes 1484CA to 1484CE are given by way of example, and a suitable number, e.g., at least one of the pin holes may be on the flange 1482C.

Referring to FIG. 5D, the insertion pins 1484D may include a plurality of pin holes 1484DA1, 1484DA2, 1484DB1, and 1484DB2, which may be formed in different combinations of size, shape, position, and number. For example, the pin holes may be formed as the small sized pin hole 1484DA1 positioned on the upper side of the flange 1482D, the large sized pin hole 1484DA2 positioned on the lower side of the flange 1482D, the large sized pin hole 1484DB 1 positioned on the upper side of the flange 1482D, the small sized pin hole 1484DA2 positioned on the lower side of the flange 1482D, etc. In this regard, the size of the pin hole 1484DA1 may be smaller than that of the pin hole 1484DA2. Also, the size of the pin hole 1484DB 1 may be larger than that of the pin hole 1484DB2.

Referring to FIG. 5E, an insertion pin 148E may include a flange 1482E which does not have any pin holes.

Referring to FIG. 5A to FIG. 5E, each of the flanges 1482A to 1482E may include flat zones FZ. The flat zones may provide the insertion pins 148A to 148E with an aligning direction or a reference point for alignment. The insertion pins 148A to 148E illustrated in FIG. 5A to FIG. 5E may be used in various combination in the baffle holes 144. The selection of the insertion pins 148 may be based on controlling the air current inside of the chamber.

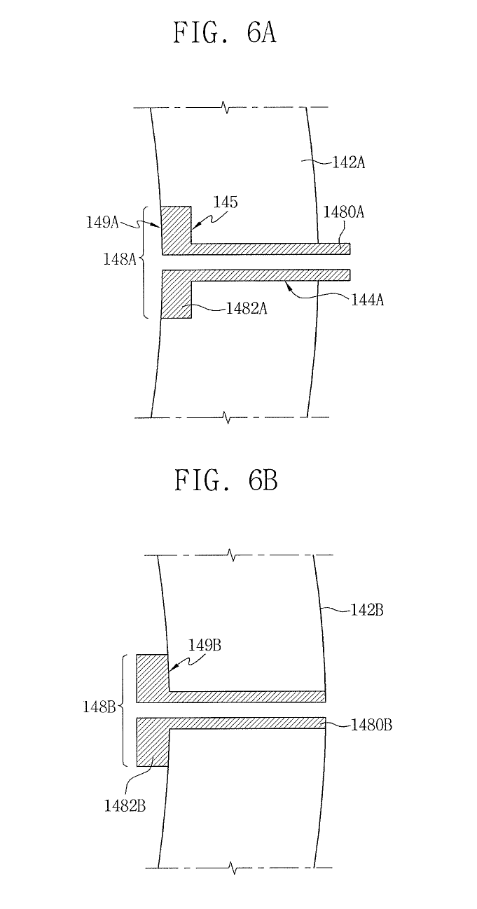

FIGS. 6A and 6B illustrate vertical sectional views that schematically illustrate insertion pins inserted into a baffle plate in accordance with various embodiments.

Referring to FIG. 6A, the insertion pin 148A may be inserted into the baffle holes 144A. One end of the body 1480A thereof may protrude from outside of the baffle plate 142A. All or part of the flange 1482A may be inserted into the baffle plate 142A. For example, each of the baffle holes 144A may have a recess 145 into which the flange 1482A can be inserted at the entrance of the baffle holes 144A.

A front surface of the flange 1482A may have a round surface 149A to conform with the surface of the baffle plate 142A.

Referring to FIG. 6B the flange 1482B of the insertion pin 148B may be positioned at an inner surface of the baffle plate 142A. That is, the flange 1482B may protrude from the inner surface of the baffle plate 142A. A front surface of the flange 1482B may have a round surface 149B to conform with the inner surface of the baffle plate 142A.

Referring to FIG. 6A and FIG. 6B, the flanges 1482A and 1482B and the bodies 1480A and 1480B may be variously combined to have various shapes (e.g., the body 1480A and the flange 1482B may be combined).

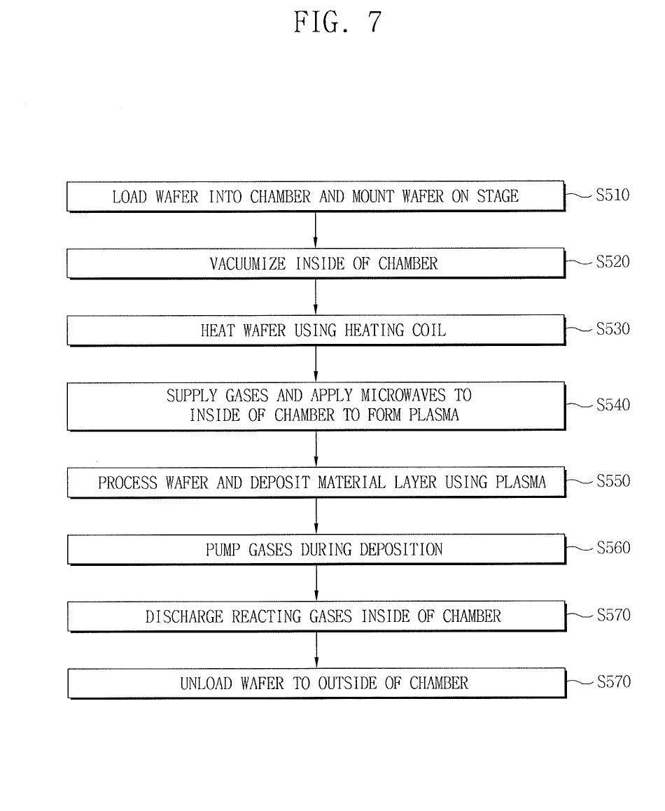

FIG. 7 illustrates a flow chart of a method of fabricating a semiconductor device using an apparatus for fabricating the semiconductor device.

Referring to FIGS. 7 and 1A to 2B, a method of fabricating the semiconductor device using the apparatus 10 may include loading a wafer 160 into a chamber 110 and mounting the wafer 160 on a stage 170 (S510).

The method may further include vacuumizing the inside of the chamber 110 (S520). For example, vacuumizing the inside of the chamber 110 may include vacuumizing the inside of the chamber 110 to a pressure of about 100 to 400 mTorr. In other embodiments, the inside of the chamber 110 may be highly vacuumizing to about 10 to 50 mTorr.

The method of fabricating the semiconductor device may further include heating the wafer 160 using a heating coil (S530). For example, heating the wafer 160 may include heating the stage 170 to about 450° C. to 550° C.

The method of fabricating the semiconductor device using the apparatus 100 for fabricating the semiconductor device may further include applying microwaves and supplying gases to the inside of the chamber 110 to form plasma (S540). The gases may include a nitrogenous gas and an inert gas. For example, the gases may be included in combinations of NH₃/Ar and/or N₂/H₂/Ar. In the case of using the gases in the combination of NH₃/Ar, NH₃ gas may be supplied at a flow rate of about 100 to 500 seem to the inside of the chamber 110 and Ar gas may be supplied at a flow rate of about 1000 to 3000 sccm (i.e., several times more than that of NH₃). Also in the case of using the gases in the combination of N₂/H₂/Ar, N₂ gas may be supplied at a flow rate of about 50 to 400 sccm to the inside of the chamber 110, H₂ gas may be supplied at a flow rate of about 20 to 200 sccm, and Ar gas may be supplied at a flow rate of about 500 to 3000 sccm. By way of example, experiments were performed using NH₃ at a flow rate of 150 sccm and Ar at a flow rate of 1500 sccm, or N₂ gas at a flow rate of 100 sccm and Ar at a flow rate of 1500 sccm. The microwaves may have a frequency of about 2.45 GHz. The microwaves may have a power of about 1.5 to 3.8 KW, for example, about 3.0 to 3.6 KW, or more specifically, about 3.3 to 3.4 KW.

The method of fabricating the semiconductor device using the apparatus 10 for fabricating the semiconductor device may further include depositing a material layer using plasma to process the wafer 160 (S550). Processing the wafer 160 using plasma may include applying an RF bias of about 13.56 MHz and about 100 to 300 W. In this process, by way of example, silicon or silicon oxide formed on the wafer 160 may be formed into silicon nitride or silicon oxynitride.

The method of fabricating the semiconductor device using the apparatus 10 for fabricating the semiconductor device may further include pumping gases while a metal layer is deposited on the wafer 160 (S560).

The method for fabricating the semiconductor device using the apparatus 10 for fabricating the semiconductor device may further include discharging the reacting gases to the gas pumping pipe 180 (S570). For example, the reacting gases inside the chamber 110 may be discharged to the outside. A vacuum state of the chamber 110 may be adjusted to atmospheric pressure. Then, the method of fabricating the semiconductor device using the apparatus 10 for fabricating the semiconductor device may further include unloading the wafer to the outside of the chamber 110 (S580).

By way of summary and review, as structures of semiconductor devices become increasingly complicated and difficult to manufacture, the importance of quality characteristics (e.g., area uniformity) of films (e.g., films used as a hard mask, an interlayer dielectric (ILD), etc.), may increase. During manufacturing, it may be difficult to distribute the reacting gases (e.g., reacting gases used for deposition or for etching) about the gas pumping pipe or a low temperature region. Thus, the reacting gases may not reach the entire surface of the wafer evenly. Such a problem may be of particular importance in an apparatus for fabricating a semiconductor device that has a multiple stage chamber structure which shares a gas injection pipe and/or a gas pumping pipe.

The above problems may be avoided by using the apparatus for fabricating a semiconductor device disclosed herein. The apparatus for fabricating a semiconductor device may include a baffle plate with baffle holes into which insertion pins may be inserted. Thus, the apparatus for fabricating a semiconductor device may allow an air current inside of the chamber to be controlled. Accordingly, the problems discussed above may be avoided by using the apparatus for fabricating a semiconductor device to distribute the reacting gases evenly on the entire surface of the wafer. Uneven distribution of gases may even be avoided in a multiple stage structure where the different stages share an injection pipe and/or a gas pumping pipe.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An apparatus for fabricating a semiconductor device, comprising:
a chamber;
a processing part inside the chamber;
a gas injection pipe connected to the chamber;
a gas pumping pipe connected to the chamber; and
a baffle assembly embedded in a wall of the chamber; wherein the baffle assembly includes:
a baffle plate having baffle holes, and
a baffle guide surrounding an outer surface of the baffle plate.

2. The apparatus as claimed in claim 1, wherein the baffle plate has a shape of a ring.

3. The apparatus as claimed in claim 1, wherein the baffle holes are arranged along a single horizontal line in the baffle plate.

4. The apparatus as claimed in claim 1, wherein the baffle holes have various sizes.

5. The apparatus as claimed in claim 1, wherein the baffle holes include a recess on a front side of the baffle plate.

6. The apparatus as claimed in claim 1, wherein the baffle plate further includes insertion pins inserted into the respective baffle holes.

7. The apparatus as claimed in claim 6, wherein each of the insertion pins includes:
a body having a diameter smaller than that of the respective baffle holes; and
a flange having a diameter larger than that of the respective baffle holes.

8. The apparatus as claimed in claim 7, wherein the body has a shape of a cylinder, and the flange has a flat zone.

9. The apparatus as claimed in claim 8, wherein the flat zone is inserted into the baffle plate.

10. The apparatus as claimed in claim 6, wherein each of the insertion pins further includes a pin hole in the flange.

11. The apparatus as claimed in claim 10, wherein the pin holes have varying positions in the flange of each of the insertion pins.

12. The apparatus as claimed in claim 10, wherein at least one of the insertion pins has a first pin hole and a second pin hole.

13. The apparatus as claimed in claim 12, wherein the first pin hole has a first diameter and the second pin hole has a second diameter, the first diameter being smaller than the second diameter.

14. The apparatus as claimed in claim 1, wherein
the processing part includes a first processing part and a second processing part,
the first processing part and the second processing part are inside the chamber,
the first processing part and the second processing part share the gas injection pipe and the gas pumping pipe,
the first processing part includes a first shower head and a first stage, and
the second processing part includes a second shower head and a second stage.

15. An apparatus for fabricating a semiconductor device, comprising:
a chamber;
a first processing part and a second processing part inside the chamber;
a gas supplying unit having a first gas distributing pipe and a second gas distributing pipe connected to the inside of the chamber, the first gas distributing pipe and the second gas distributing pipe divaricating from the gas supplying unit and being connected to the first processing part and the second processing part, respectively;
a gas pumping unit having a first gas collecting pipe and a second gas collecting pipe connected to the inside of the chamber, the first gas collecting pipe and the second gas collecting pipe being connected to the first processing part and the second processing part, respectively;
a first baffle assembly surrounding the first processing part and embedded in a wall of the chamber, the first baffle assembly including:
a first baffle plate having first baffle holes, and
first insertion pins inserted into the first baffle holes; and
a second baffle assembly surrounding the second processing part and embedded in the wall of the chamber, the second baffle assembly including:
a second baffle plate having second baffle holes, and
second insertion pins inserted into the second baffle holes.

16. The apparatus as claimed in claim 15, wherein the first gas collecting pipe and the second gas collecting pipe divaricate from the gas pumping unit.

17. The apparatus as claimed in claim 15, wherein:
the first insertion pins are inserted into the first baffle holes according to a first arrangement,
the second insertion pins are inserted into the second baffle holes according to a second arrangement, and
the first arrangement is different from the second arrangement.

18. An apparatus for fabricating a semiconductor device, comprising:
a chamber with a gas inlet and a gas outlet;
a stage inside the chamber; and
a baffle assembly in a gas flow path between the gas inlet and the gas outlet, the baffle assembly including:
baffle holes defining the gas flow path through the baffle assembly, and
at least one insertion pin inside at least one of the baffle holes, the at least one insertion pin at least partially obstructing the gas flow path through the at least one baffle hole.

19. The apparatus as claimed in claim 18, wherein the baffle assembly includes first and second insertion pins in respective first and second baffle holes, and the first and second insertion pins obstruct the gas flow path through the respective first and second baffle holes to varying degrees.

20. The apparatus as claimed in claim 19, wherein the first insertion pin completely obstructs the gas flow path through the first baffle hole.
